(19) United States
(12) Patent Application Publication
(10) Pub. No.: US 2020/0194577 A1
(43) Pub. Date: Jun. 18, 2020

(54) GAN BASED HEMT DEVICE RELAXED BUFFER STRUCTURE ON SILICON

(71) Applicant: Intel Corporation, Santa Clara, CA (US)

(72) Inventors: Glenn GLASS, Portland, OR (US); Sansaptak DASGUPTA, Hillsboro, OR (US); Han Wui THEN, Portland, OR (US); Marko RADOSAVLJEVIC, Portland, OR (US); Paul FISCHER, Portland, OR (US); Anand MURTHY, Portland, OR (US); Alexander BADMAEV, Portland, OR (US); Michael S. BEUMER, Portland, OR (US); Sandrine CHARUE-BAKKER, Portland, OR (US)

(21) Appl. No.: 16/219,156

(22) Filed: Dec. 13, 2018

(51) Int. Cl. H01L 29/778; H01L 29/20; H01L 29/06; H01L 29/423; H01L 21/02; H01L 29/15; H01L 29/66

(52) U.S. Cl. CPC H01L 29/778; H01L 29/2003; H01L 29/0673; H01L 29/66462; H01L 21/0254; H01L 29/15; H01L 29/4236

(57) ABSTRACT

An HEMT semiconductor structure is disclosed. The semiconductor structure includes a substrate, a GaN layer above the substrate, a first TDD reducing structure above the substrate and a polarization layer above the GaN layer.

### TECHNICAL FIELD

Embodiments of the disclosure pertain to providing a relaxed buffer structure on silicon, in particular, to GaN based HEMT relaxed buffer structure on silicon.

### BACKGROUND

GaN is a wide-band gap semiconductor that can be used in short wavelength, high-power or high-temperature electronic devices. The GaN layer may be deposited on a relaxed stack containing AlN and other Al and Ga containing nitride alloys. As such the GaN layer is grown under conditions of compressive stress and hence may not be microstructurally flat. If the surface is rippled or contains undulations, downstream processing may be adversely affected. Threading dislocation density (TDD) which can be caused by lattice parameter differences between layers and coefficient of thermal expansion mismatches between the GaN layer and a hetero-epitaxial substrate can lead to reduction of crystal quality. It should be appreciated that depositing thick relaxed buffer layers on Si substrates is enabling for large scale integration in contrast to group III-V substrates that would be limited in size and quantity.

In a conventional approach an elaborate and thick buffer layer is formed between the Si substrate and a GaN layer to reduce threading dislocation density (TDD) and to control stress and hence wafer bow for Group III nitride transistors that are fabricated on the Si substrate. However, the cost of fabricating a thick multilayer buffer layer between a Si substrate and a GaN layer is high and can be unsatisfactory for many current applications.

### BRIEF DESCRIPTION OF THE DRAWINGS

FIG. 1A illustrates a high electron mobility (HEMT) structure including a buffer stack of a previous approach.

FIG. 1B illustrates a HEMT structure that includes a buffer stack that includes a tensile layer according to an embodiment.

FIG. 1C illustrates an HEMT structure that includes a buffer stack that includes a plurality of tensile layers according to an embodiment.

FIGS. 2A-2C illustrate HEMT structures that include a buffer stack that includes a superlattice layer according to an embodiment.

FIG. 3 illustrates an HEMT structure that includes a buffer that includes an annealed GaN layer according to an embodiment.

FIG. 4 illustrates an HEMT structure that includes a buffer that includes a Van der Waals nanosheet layer according to an embodiment.

FIGS. 5A-5E illustrates cross-sections of HEMT structures that include a relaxed buffer structure at various stages of the fabrication of the HEMT structures according to an embodiment.

FIG. 6 illustrates a computing device in accordance with one implementation of an embodiment.

FIG. 7 illustrates an interposer that includes one or more implementations of the embodiments.

### DESCRIPTION OF THE EMBODIMENTS

A GaN based HEMT device relaxed buffer structures on silicon is described. It should be appreciated that although embodiments are described herein with reference to example GaN based HEMT device relaxed buffer structures on silicon implementations, the disclosure is more generally applicable to GaN based HEMT device relaxed buffer structures on silicon implementations as well as other type GaN based HEMT device relaxed buffer structures on silicon implementations. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features, such as integrated circuit design layouts, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

GaN is a wide-band gap semiconductor that can be used in short wavelength, high-power or high-temperature electronic devices. The GaN layer can grow with undulations that impede downstream processing. Threading dislocations (TDs) which can be caused by lattice and coefficient of thermal expansion mismatches between the GaN layer and a hetero-epitaxial substrate can lead to reduction of crystal quality.

In a conventional approach an elaborate and thick buffer layer is formed between a Si substrate and a GaN layer to reduce threading dislocation density (TDD) and to control stress and wafer bow for Group III nitride transistors that are fabricated on the Si substrate. However, the thick buffer layer can be unsatisfactory for some applications. Thick buffer stacks are not ideal due to long processing times (reduced output), higher precursor usage, and higher cost of manufacturing.

Approaches that address the shortcomings of such previous approaches are disclosed herein. As a part of the approaches, a provision of relaxed buffer layers that enable the formation of GaN based devices on Si substrates are provided. In the disclosed embodiments, the thickness of the buffer layers are reduced while maintaining acceptable levels of TDD and surface roughness. In an embodiment structures and methods to address limitations related to the use of multilayer buffer layers is provided (e.g., edge cracking due to tensile stress, wafer bow, roughness, high TDD and stack thickness requirements).

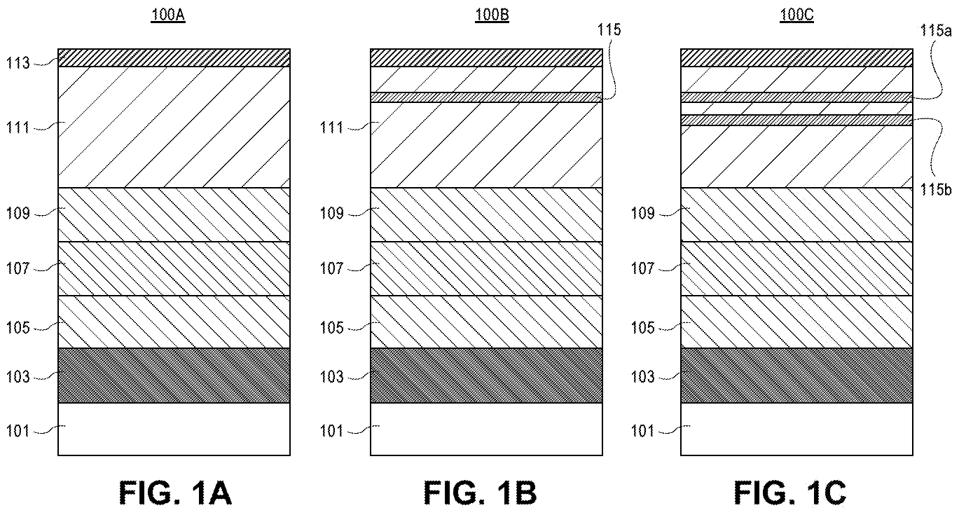

FIG. 1A shows an HEMT structure 100A including a buffer stack of a previous approach. FIG. 1A shows substrate 101, a buffer layer that includes AlN layer 103, a series of AlGaN layers with successively higher Ga concentrations: AlGaN layer 105 and AlGaN layer 107, AlGaN layer 109, GaN 111 and polarization stack 113. In an embodiment, the AlGaN layer 105 is a 75 percent AlGaN composition, the AlGaN layer 107 is a 48 percent AlGaN composition, and the AlGaN layer 109 is a 25 percent AlGaN composition. In other embodiments, other suitable compositions of AlGaN material can be used to implement the AlGaN layer 105, the AlGaN layer 107 and the AlGaN layer 109.

Referring to FIG. 1A, the AlN layer 103 is formed on substrate 101. The AlGaN layer 105 is formed on AlN layer 103, the AlGaN layer 107 is formed on AlGaN layer 105. The AlGaN layer 109 is formed on AlGaN layer 107. The GaN layer 111 is formed on AlGaN layer 109. The polarization stack 113 is formed on GaN layer 111. In an embodiment, the substrate 101 can be formed from Si. In other embodiments, the substrate can be formed from other material. In an embodiment, the polarization stack 113 can be formed from an InAlN, AlGaN or InAlGaN layer and an AlN under-layer and an optional insulator cap (options include CN, BN, SiN etc). In other embodiments, the polarization stack 113 can be formed from other materials. In an embodiment the AlN layer 103 can have a thickness of 170 nm. In other embodiments, the AlN layer 103 can have other thicknesses. In an embodiment, the AlGaN layer 105 can have a thickness of 150 nm. In other embodiments, the AlGaN layer 105 can have other thicknesses. In an embodiment, the AlGaN layer 107 can have a thickness of 250 nm. In other embodiments, the AlGaN layer 107 can have other thicknesses. In an embodiment, the AlGaN layer 109 can have a thickness of 300nm. In other embodiments, the AlGaN layer 109 can have other thicknesses. In an embodiment, the GaN layer 111 can have a thickness of 1 um. In other embodiments, the GaN layer 111 can have other thicknesses. FIGS. 1B and 1C illustrate the manner in which relaxed buffer layers that address TDD and undulations that can impede downstream processing are provided.

FIG. 1B shows an HEMT structure 100B that includes a buffer stack according to an embodiment. The HEMT structure 100B includes in addition to the structures shown in FIG. 1A, tensile layer 115. Referring to FIG. 1B, tensile layer 115 is formed in the GaN layer 111. In an embodiment, the tensile layer 115 can be formed from AlGaN with Al compositions greater than 25 atomic % of the group III atoms, AlN, SiN, or BN. In other embodiments, the tensile layer 115 can be formed from other material. FIG. 1C shows an HEMT structure 100C that includes a buffer stack according to another embodiment. The HEMT structure 100C includes in addition to the structures shown in FIG. 1A, tensile layers 115a and 115b. Referring to FIG. 1C, tensile layer 115a and tensile layer 115b are formed in the GaN layer 111. In an embodiment, the tensile layer 115a and the tensile layer 115b can be formed from AlN, SiN, or BN. In other embodiments, the tensile layer 115a and the tensile layer 115b can be formed from other material.

In FIGS. 1B and 1C, the HEMT structures 100B and 100C include relaxed buffer structures that include surface smoothing features and that are formed on a Si substrate. The HEMT structures 100B and 100C include components that address the problem of Group III nitride transistors that are fabricated on a Si substrate that require an elaborate and thick buffer layer to reduce threading dislocation density (TDD) and to control stress and wafer bow. In the FIG. 1B embodiment, because the GaN layer is compressive and can grow with undulations that impede downstream processing, a single tensile layer 115 can be formed in the GaN layer near the top of the GaN layer to assist in smoothing out the surface layer. In the FIG. 1C embodiment, alternating tensile layers 115a and 115b can be formed in the GaN layer near the top of the GaN layer to assist in smoothing out the surface layer. In other embodiments, more than two tensile layers can be used. In an embodiment, the tensile layers improve planarity of the surface of the GaN layer in-situ. In an embodiment, the tensile layers can undergo passivation doping using iron or C. In other embodiments, the tensile layers can undergo passivation doping using other materials. In an embodiment, an approximately 20 nm polarization layer can be formed on the GaN layer. In other embodiments, a polarization layer having other thicknesses can be formed on the GaN layer. In an embodiment, the maximum and minimum roughness in a 100 um line can improve from 40 nm to 10 nm. In other embodiments, other improvements in maximum and minimum roughness can be made. In an embodiment, various configurations and material makeup of the tensile layers near the top region of the GaN layer can be used. In an embodiment, AlN, SiN, or BN in any combination can be used. In other embodiments, materials other than AlN, SiN or BN in suitable combinations can be used. In an embodiment, the thick GaN layer can be replaced with a thick AlGaN layer and a thin GaN layer at top. In other embodiments, the thick GaN layer can be replaced with other materials.

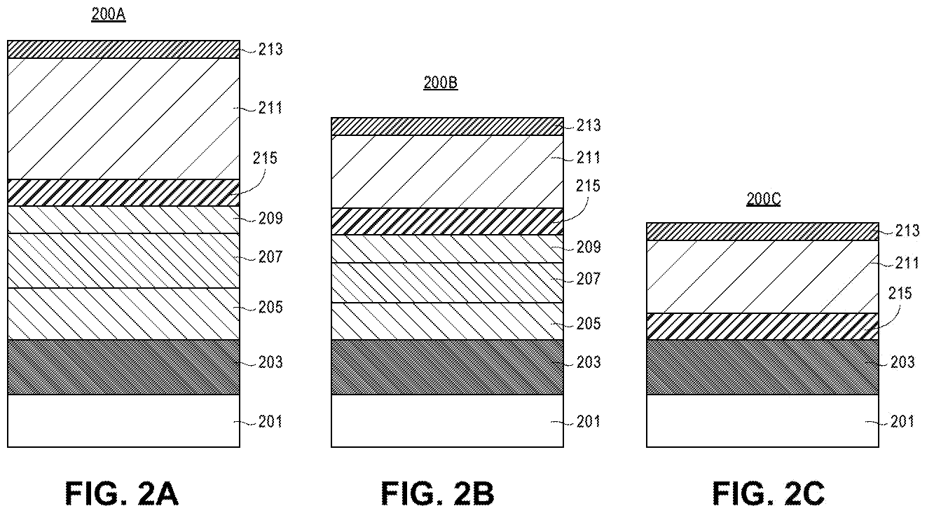

FIGS. 2A, 2B and 2C show HEMT structures 200A, 200B and 200C that include relaxed buffer stacks that include a superlattice layer that addresses TDD and undulations that can impede downstream processing according to an embodiment. Referring to FIG. 2A, the HEMT structure 200A includes a substrate 201, a buffer layer that includes AlN layer 203, AlGaN layer 205 and AlGaN layer 207, AlGaN layer 209, GaN layer 211, polarization stack 213 and superlattice layer 215. Referring to FIG. 2A, the AlN layer 203 is formed on substrate 201. The AlGaN layer 205 is formed on AlN layer 203, the AlGaN layer 207 is formed on AlGaN layer 205. The AlGaN layer 209 is formed on AlGaN layer 207. The superlattice layer 215 is formed on AlGaN layer 209. The GaN layer 211 is formed on superlattice layer 215. The polarization stack 213 is formed on GaN layer 211. In an embodiment, the substrate 201 can be formed from Si. In other embodiments, the substrate can be formed from other material. In an embodiment, the polarization stack 213 can be formed from an InAlN layer, an AlGaN layer or an InAlGaN layer. In other embodiments, the polarization stack 213 can be formed from other materials. In an embodiment, the superlattice layer 215 is a stack of alternating types of materials. In an embodiment, the superlattice layer 215 can be formed from alternating layers of semiconductor materials. In other embodiments, the superlattice layer 215 can be formed from alternating layers of other types of materials. In an embodiment, the superlattice layer 215 can be formed from alternating layers of pure GaN and a 25 atomic percent composition of AlGaN (25% of the group III atoms). In other embodiments, the superlattice layer 215 can be formed from other materials having other atomic percent compositions. In an embodiment, the superlattice layer 215 can have a thickness of 150 nm. In other embodiments, the superlattice layer 215 can have other thicknesses. In an embodiment, the dimensions of the aforementioned components of HEMT structure 200A are similar to their counterparts in HEMT structure 100A of FIG. 1A, except that AlGaN layer 209 has a thickness of 150 nm as opposed to 300 nm. Referring to FIG. 2B, as compared to the HEMT structure 200A, HEMT structure 200B retains the superlattice layer 215 but incudes a thinner buffer layer. In particular, the thickness of the AlGaN layer 207 of the buffer layer is reduced from 250 nm to 150 nm. In other embodiments, the thickness of the AlGaN layer 207 of the buffer layer can be reduced to other thicknesses. Referring to FIG. 2C, as compared to the HEMT structure 200A, HEMT structure 200C retains the superlattice layer 215 but incudes a much thinner buffer layer. In particular, the AlGaN layers 205, 207 and 209 of the buffer layer are eliminated.

In FIGS. 2A-2C, the HEMT structures 200A, 200B and 200C include a relaxed buffer structure for use in high performance GaN based HEMT devices. The HEMT structures 200A, 200B and 200C address the problem of Group III nitride transistors fabricated on a Si substrate that require an elaborate and thick buffer layer to reduce threading dislocation density (TDD) and to control stress and wafer bow by reducing the total thickness of the buffer layer while maintaining acceptable TDD. More specifically, TDD levels are reduced at a given thickness or thickness is reduced at a given TDD level by replacing the AlGaN set of layers with a thin superlattice structure. In an embodiment, given the thinner buffer layer, precaution can be taken to avoid Si doping or the unintentional production of 2DEG, and to maintain insulating properties. For example, in an embodiment, in a GaN layer of the superlattice, carbon doping can be used to quench 2DEG charge at interfaces. Moreover, iron, magnesium, zinc or other p-type doping can be used to quench stray dopant to make the stack more insulating. In an embodiment, the period, composition, and thickness of the buffer stack can be tuned to the thickness of the GaN layer.

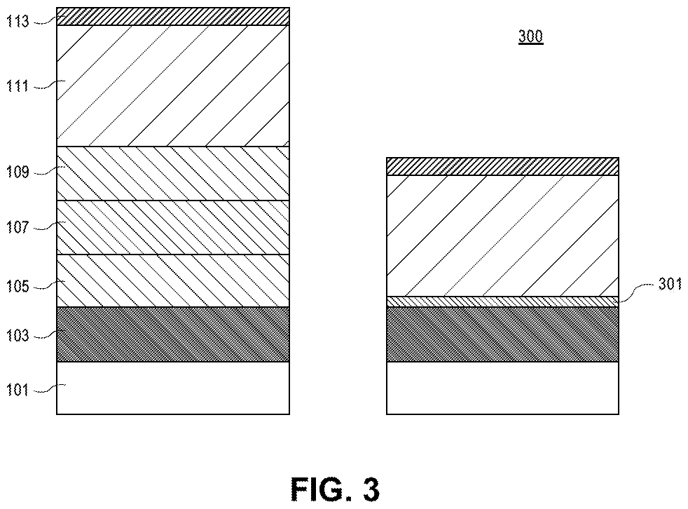

FIG. 3 shows a HEMT structure 300 that includes buffer stack that includes an annealed GaN layer according to an embodiment. Referring to FIG. 3, as compared to the HEMT structure 100A HEMT structure 300 includes an annealed GaN layer 301 and provides a much thinner buffer structure. In particular, the AlGaN layers, e.g., 105, 107 and 109 in FIG. 1A of the HEMT structure 100A, have been eliminated.

In FIG. 3, the HEMT structure 300 includes a GaN based HEMT and MOS device short stack with a relaxed buffer structure. The HEMT structure 300 addresses the problem of Group III nitride transistors fabricated on a Si substrate that require an elaborate and thick buffer layer to reduce threading dislocation density (TDD) and to control stress and wafer bow by reducing the total thickness of the buffer layer while maintaining acceptable TDD. In an embodiment, TDD levels are reduced at a given thickness or the thickness is reduced at a given TDD level by replacing the AlGaN set of layers with a thin defective GaN layer deposited at a low temperature, for example below 800 C, that is subsequently annealed to provide a more highly relaxed epitaxial template for GaN growth. In an embodiment, the in-plane lattice constant of the GaN layer of the HEMT structure 300 is far less tetragonally strained relative to the AlN initial template layer than that of the HEMT structure 100A that is fabricated according to the approach of FIG. 1. In an embodiment, the TDD target is 1E9 per cm2 or less. In other embodiments, other TDD targets can be used. In an embodiment, a thin 10-40 nm initial GaN layer of GaN 0.5-5 um is deposited on the initial AlN template layer. In an embodiment, the HEMT structure 300 can include enhancement mode and depletion mode transistors, field plates, diodes, polarization layers and various stack types. In an embodiment, hydrazine or other such nitrogen compounds can be used to enable equivalent relaxation in a shorter stack owing to ability to fully nitride the group III materials at a lower temperature than used in the conventional ammonia based reaction, e.g., to greatly reduce or eliminate AlGaN graded layers.

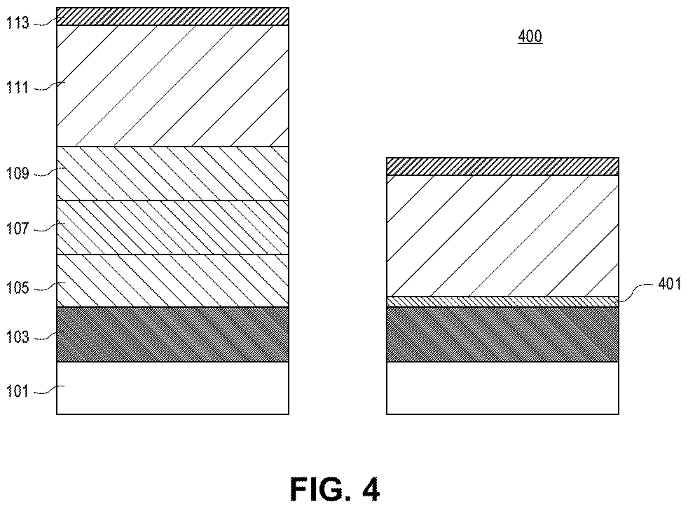

FIG. 4 shows a HEMT structure 400 that includes a layer of nanosheet material according to an embodiment. Referring to FIG. 4, as compared to the HEMT structure 100A of FIG. 1A, HEMT structure 400 includes a layer of nanosheet material 401 and a thinner buffer layer. In particular, the AlGaN layers, e.g., 105, 107 and 109 of the buffer layer of the HEMT structure 100A in FIG. 1A, have been eliminated.

In FIG. 4, the HEMT structure 400 includes a GaN based HEMT and MOS device nanosheet assisted short relaxed buffer stack structure. The HEMT structure 400 addresses the problem of Group III nitride transistors fabricated on a Si substrate that require an elaborate and thick buffer layer to reduce threading dislocation density (TDD) and to control stress and hence wafer bow. In an embodiment, the total thickness is reduced and an acceptable TDD is maintained by reducing TDD levels at a given thickness or reducing thickness at a given TDD level by replacing the AlGaN set of layers with a highly compliant nanosheet structure 401. In an embodiment, the nanosheet structure 401 is a two-dimensional nanostructure with a thickness ranging from 1 to 100 nm. In other embodiments, the nanosheet structure 401 can have other thicknesses. In an embodiment, the nanosheet structure 401 includes Van Der Waals nanosheet material that includes graphene or MXene materials (aluminum oxides containing other metals and having two-dimensional nature analogous to graphene). In other embodiments, the nanosheet structure 401 can include other materials. In an embodiment, the in-plane lattice constant of the GaN is far less tetragonally strained than one fabricated by the previous approach of FIG. 1A. In an embodiment, the TDD target is 1E9 per cm2 or less. In other embodiments, other TDD targets can be used. In an embodiment, a graphene nanosheet can be formed 1, 2 or 3 layers above AlN and below a GaN layer of 0.5-5 um thickness. In an embodiment, the HEMT structure 400 can include enhancement mode and depletion mode transistors, field plates, diodes, polarization layers and various stack types.

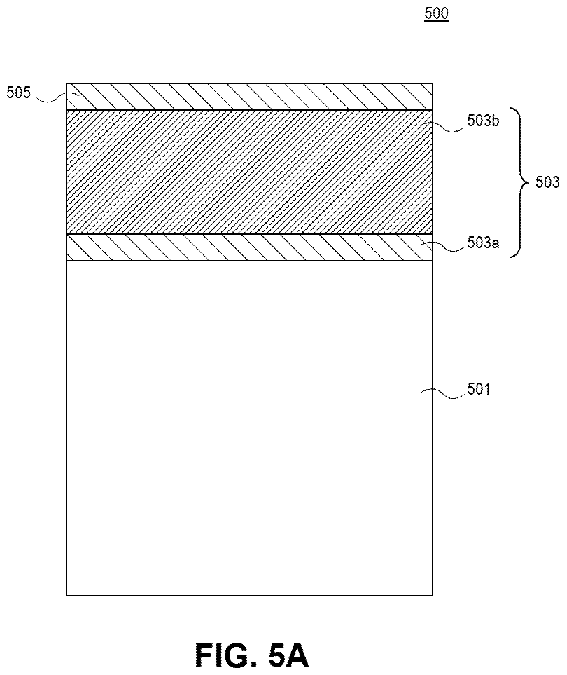

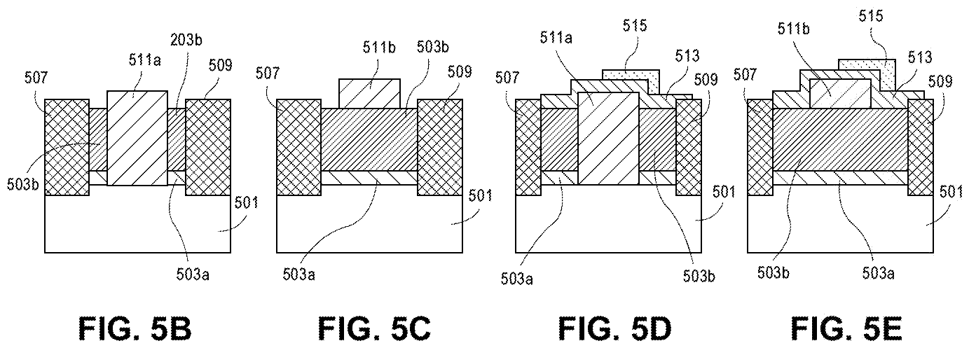

FIGS. 5A-5E illustrates cross-sections of a HEMT structure 500 that includes a relaxed buffer structure at (in FIG. 5A) and respective devices that are derived from the HEMT structure 500 (in FIGS. 5B-5E) according to an embodiment. Referring to FIG. 5A, after a plurality of operations a HEMT structure 500 includes a relaxed buffer stack 501, a polarization stack 503 and capping layer 505 (optional). In an embodiment, the polarization stack 503 includes AlN layer 503a and polarization layer 503b. In an embodiment, the polarization layer 503b can include but is not limited to InAlN, AlGaN or InAlGaN. In an embodiment, the capping layer 505 can include SiN and SiO2, other insulating metal oxides or nitride. In an embodiment, the insulating nitride can include BN, SiN or CN. In other embodiments, the insulating nitride can include other materials.

FIGS. 5B-5E are illustrations of cross-sections of respective devices derived from the HEMT structure 500 formed in operations subsequent to those that result in the cross-section shown in FIG. 5A, and that correspond to the formation of enhancement mode, depletion mode, enhancement mode with field plate and depletion mode with field plate, type transistors.

Referring to FIG. 5B, as part of the fabrication of an enhancement mode device, subsequent to operations that result in the cross-section shown in FIG. 5A, source 507 and drain 509 regions are formed. In an embodiment, for enhancement mode devices, a gate recess is formed. In addition, in an embodiment, a gate dielectric can be formed in the gate recess. In other embodiments, a gate dielectric may not be formed. Subsequently, the gate electrode 511a is formed. In an embodiment, the gate electrode 511a can be formed by deposition. In other embodiments, the gate electrode 511a can be formed in other manners.

Referring to FIG. 5C, as part of the fabrication of a depletion mode device, subsequent to operations that result in the cross-section shown in FIG. 5A, source 507 and drain 509 regions are formed. In an embodiment, for depletion mode devices, a gate electrode 511b is formed on the polarization layer 503b. In addition, in an embodiment, a gate dielectric can be formed. In other embodiments, a gate dielectric may not be used. In an embodiment, the gate electrode 511b can be formed by deposition. In other embodiments, the gate electrode 511b can be formed in other manners.

Referring to FIG. 5D, as part of the fabrication of an enhancement mode device, subsequent to operations that result in the cross-section shown in FIG. 5A, source 507 and drain 509 regions are formed. In an embodiment, for enhancement mode devices, a gate recess is formed. In addition, in an embodiment, a gate dielectric can be formed. In other embodiments, a gate dielectric may not be formed. Subsequently, the gate electrode 511a is formed in the gate recess. In an embodiment, the gate electrode 511a can be formed by deposition. In other embodiments, the gate electrode 511a can be formed in other manners. Thereafter, an insulator 513 is formed to cover a top portion of the gate electrode 511a. In an embodiment, a field plate 515 is formed on the insulator 513 above the gate electrode 511a.

Referring to FIG. 5E, as part of the fabrication of a depletion mode device, subsequent to operations that result in the cross-section shown in FIG. 5A, source 507 and drain 509 regions are formed. In an embodiment, for depletion mode devices, a gate electrode 511b is formed. In addition, in an embodiment, a gate dielectric is formed. In other embodiments, a gate dielectric may not be formed (used). In an embodiment, the gate electrode 511b can be formed by deposition. In other embodiments, the gate electrode 511b can be formed in other manners. Thereafter, an insulator 513 is formed to cover a top portion of the gate electrode 511b. In an embodiment, a field plate 515 is formed on the metal insulator above the gate electrode.

It should be appreciated that in other embodiments the HEMT devices of FIGS. 5B-5E can include a thin oxide layer (not shown) underneath the gate to form a MOS HEMT structure. Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO2) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO2), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

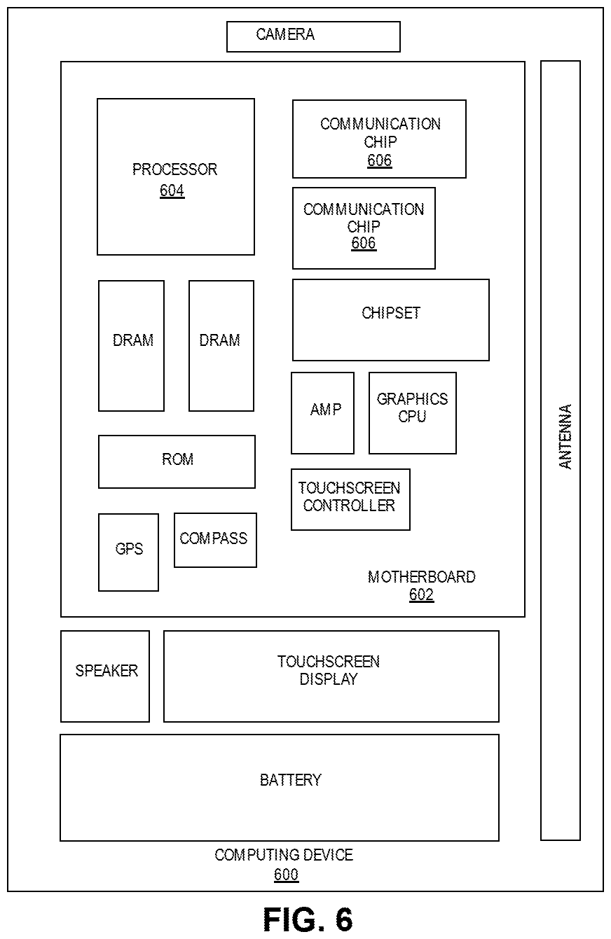

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip includes one or more devices, such as MOS-FET transistors built in accordance with implementations of the invention.

In further implementations, another component housed within the computing device 600 may contain an integrated circuit die that includes one or more devices, such as MOS-FET transistors built in accordance with implementations of the invention.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

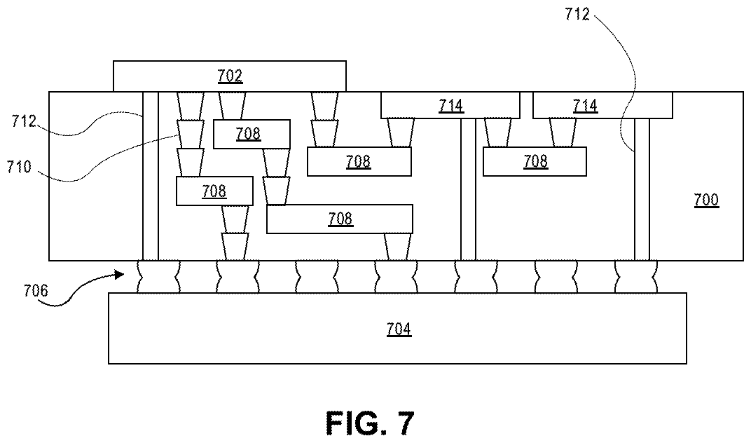

FIG. 7 illustrates an interposer 700 that includes one or more embodiments of the invention. The interposer 700 is an intervening substrate used to bridge a first substrate 702 to a second substrate 704. The first substrate 702 may be, for instance, an integrated circuit die. The second substrate 704 may be, for instance, a memory module, a computer motherboard, or another integrated circuit die. Generally, the purpose of an interposer 700 is to spread a connection to a wider pitch or to reroute a connection to a different connection. For example, an interposer 700 may couple an integrated circuit die to a ball grid array (BGA) 706 that can subsequently be coupled to the second substrate 704. In some embodiments, the first and second substrates 702/704 are attached to opposing sides of the interposer 700. In other embodiments, the first and second substrates 702/704 are attached to the same side of the interposer 700. And in further embodiments, three or more substrates are interconnected by way of the interposer 700.

The interposer 700 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 700. In accordance with embodiments of the invention, apparatuses or processes disclosed herein may be used in the fabrication of interposer 700.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

Example embodiment 1: An HEMT semiconductor structure including a substrate, a GaN layer coupled to the substrate, a first TDD reducing structure coupled to the substrate including one or more tensile layers in the GaN layer, and a polarization layer coupled to the GaN layer.

Example embodiment 2: The HEMT semiconductor structure of example embodiment 1, further comprising a second TDD reducing structure coupled to the substrate that includes a plurality of layers of materials.

Example embodiment 3: The HEMT semiconductor structure of example embodiment 2, wherein the plurality layers of materials include respective layers of AlGaN that have respective percentages of AlGaN.

Example embodiment 4: The HEMT semiconductor structure of example embodient 2, wherein the plurality layers of materials include respective layers of AlGaN that have respective thicknesses.

Example embodiment 5: The HEMT semiconductor structure of example embodiment 1, wherein an AlN layer is coupled to the top surface of the substrate.

Example embodiment 6: The HEMT semiconductor structure of example embodiment 1, 2, 3, 4, or 5 wherein the substrate is formed from silicon.

Example embodiment 7: An HEMT semiconductor structure including a substrate, a first TDD reducing component including a superlattice structure coupled to the substrate, a GaN layer coupled to the top surface of the superlattice structure, and a polarization layer coupled to the GaN layer.

Example embodiment 8: The HEMT semiconductor structure of example embodiment 7, further comprising a second TDD reducing structure that is coupled to the substrate and that includes a plurality of layers of materials.

Example embodiment 9: The HEMT semiconductor structure of example embodiment 8, wherein the plurality of layers of materials include respective layers of AlGaN that have respective percentages of AlGaN.

Example embodiment 10: The HEMT semiconductor structure of example embodiment 8, wherein the plurality layers of materials include respective layers of AlGaN that have respective thicknesses.

Example embodiment 11: The HEMT semiconductor structure of example embodiment 7, wherein an AlN layer is coupled to the top surface of the substrate.

Example embodiment 12: The HEMT semiconductor structure of example embodiment 7, 8, 9, 10 or 11 wherein the substrate includes silicon.

Example embodiment 13: An HEMT semiconductor structure, including a substrate, a first TDD reducing component including an annealed layer coupled to the substrate, a GaN layer coupled to the top surface of the annealed layer, and a polarization layer coupled to the GaN layer.

Example embodiment 14: The HEMT semiconductor structure of example embodiment 13, wherein the annealed layer is an annealed GaN layer.

Example embodiment 15: The HEMT semiconductor structure of example embodiment 13, wherein an AlN layer is coupled to the top surface of the substrate.

Example embodiment 16: The HEMT semiconductor structure of example embodiment 13, 14 or 15 wherein the substrate includes silicon.

Example embodiment 17: A HEMT semiconductor structure, including a substrate, a first TDD reducing component including a Van der Waals nanosheet layer coupled to the substrate, a GaN layer coupled to the top surface of the Van der Waals nanosheet layer, and a polarization layer coupled to the GaN layer.

Example embodiment 18: The HEMT semiconductor structure of example embodiment 17, wherein the Van der Waals nanosheet layer includes graphene.

Example embodiment 19: The HEMT semiconductor structure of example embodiment 17, 18 or 19 wherein the Van der Waals nanosheet layer includes insulating MXene materials.

Example embodiment 20: The HEMT semiconductor structure of example embodiment 17, wherein an AlN layer is coupled to the top surface of the substrate.

What is claimed is:

1. A high electron mobility (HEMT) semiconductor structure, comprising:
a substrate;
a GaN layer above the substrate;
a first threading dislocation density (TDD) reducing structure above the substrate including one or more tensile layers in the GaN layer; and
a polarization layer above the GaN layer.

2. The HEMT semiconductor structure of claim 1, further comprising a second TDD reducing structure above the substrate that includes a plurality of layers of materials.

3. The HEMT semiconductor structure of claim 2, wherein the plurality layers of materials include respective layers of AlGaN that have respective percentages of AlGaN.

4. The HEMT semiconductor structure of claim 2, wherein the plurality layers of materials include respective layers of AlGaN that have respective thicknesses.

5. The HEMT semiconductor structure of claim 1, wherein an AlN layer is above the top surface of the substrate.

6. The HEMT semiconductor structure of claim 1, wherein the substrate is formed from silicon.

7. An HEMT semiconductor structure, comprising:
a substrate;
a first TDD reducing component including a superlattice structure above the substrate;
a GaN layer above the top surface of the superlattice structure; and
a polarization layer above the GaN layer.

8. The HEMT semiconductor structure of claim 7, further comprising a second TDD reducing structure that is above the substrate and that includes a plurality of layers of materials.

9. The HEMT semiconductor structure of claim 8, wherein the plurality of layers of materials include respective layers of AlGaN that have respective percentages of AlGaN.

10. The HEMT semiconductor structure of claim 8, wherein the plurality layers of materials include respective layers of AlGaN that have respective thicknesses.

11. The HEMT semiconductor structure of claim 7, wherein an AlN layer is above the top surface of the substrate.

12. The HEMT semiconductor structure of claim 7, wherein the substrate includes silicon.

13. An HEMT semiconductor structure, comprising:
a substrate;
a first TDD reducing component including an annealed layer above the substrate;
a GaN layer above the top surface of the annealed layer; and
a polarization layer above the GaN layer.

14. The HEMT semiconductor structure of claim 13, wherein the annealed layer is an annealed GaN layer.

15. The HEMT semiconductor structure of claim 13, wherein an AlN layer is above the top surface of the substrate.

16. The HEMT semiconductor structure of claim 13, wherein the substrate includes silicon.

17. A HEMT semiconductor structure, comprising:
a substrate;
a first TDD reducing component including a Van der Waals nanosheet layer above the substrate;
a GaN layer coupled to the top surface of the Van der Waals nanosheet layer; and
a polarization layer above the GaN layer.

18. The HEMT semiconductor structure of claim 17, wherein the Van der Waals nanosheet layer includes graphene.

19. The HEMT semiconductor structure of claim 17, wherein the Van der Waals nanosheet layer includes insulating MXene materials.

20. The HEMT semiconductor structure of claim 17, wherein an AlN layer is above the top surface of the substrate.
